(19) United States
(12) Patent Application Publication
(10) Pub. No.: US 2005/0245086 A1
(43) Pub. Date: Nov. 3, 2005

(54) Adaptive electropolishing using thickness measurement and removal of barrier and sacrificial layers

(75) Inventors: Hui Wang, Fremont, CA (US); Muhammed Afnan, Fremont, CA (US); Peihaur Yih, Boonton, NJ (US); Damon L. Koehler, Fremont, CA (US); Chaw-Chi Yu, Saratoga, CA (US)

Correspondence Address: MORRISON & FOERSTER LLP, 425 MARKET STREET, SAN FRANCISCO, CA, 94105-2482, US

(73) Assignee: ACM Research, Inc., Fremont, CA (US)

(21) Appl. No.: 10/520,493

(22) PCT Filed: Jul. 22, 2003
(86) PCT No.: PCT/US03/22928

§ 371 Date: Jan. 6, 2005

Related U.S. Application Data
(60) Provisional application No. 60/397,941, filed on Jul. 22, 2002.
(60) Provisional application No. 60/403,996, filed on Aug. 17, 2002.

(51) Int. Cl. H01L 21/302; H01L 21/461

(52) U.S. Cl. 438/690

(57) ABSTRACT

A metal layer formed on a semiconductor wafer is adaptively electropolished. A portion of the metal layer is electropolished, where portions of the metal layer are electropolished separately. Before electropolishing the portion, a thickness measurement of the portion of the metal layer to be electropolished is determined. The amount that the portion is to be electropolished is adjusted based on the thickness measurement. A metal layer formed on a semiconductor wafer is polished, where the metal layer is formed on a barrier layer, which is formed on a dielectric layer having a recessed area and a non-recessed area, and where the metal layer covers the recessed area and the non-recessed areas of the dielectric layer. The metal layer is polished to remove, the metal layer covering the non-recessed area. The metal layer in the recessed area is polished to a height below the non-recessed area, where the height is equal to or greater than a thickness of the barrier layer.

### CROSS-REFERENCE TO RELATED APPLICATIONS

The present application claims priority of earlier filed provisional application U.S. Ser. No. 60/397,941, entitled METHOD FOR ELECTROPOLISHING METAL FILM ON SUBSTRATE, filed on Jul. 22, 2002, and U.S. Ser. No. 60/403,996, entitled METHODS FOR BARRIER AND SACRIFICIAL LAYER REMOVAL, filed on Aug. 17, 2002, the entire contents of which are incorporated herein by reference.

### BACKGROUND

1. Field of the Invention

The present application relates to electropolishing a metal film formed on a substrate, and more particularly to adaptively electropolishing a metal film formed on a semiconductor wafer using the thickness measurements of the metal film. The present application also relates to removal of barrier and sacrificial layers during polishing and plasma etching processes.

2. Related Art

Semiconductor devices are manufactured or fabricated on semiconductor wafers using a number of different processing steps to create transistor and interconnection elements. To form transistor and/or interconnection elements, the semiconductor wafer may undergo, for example, masking, etching, and deposition processes to form the desired electronic circuitry of the semiconductor devices. In particular, in a damascene process, multiple masking and etching steps can be performed to form a pattern of recessed areas in a dielectric layer on a semiconductor wafer that serve as trenches and vias for the interconnections. A deposition process may then be performed to deposit a metal layer over the semiconductor wafer thereby depositing metal both in the trenches and vias and also on the non-recessed areas of the semiconductor wafer. To isolate the interconnections, such as patterned trenches and vias, the metal layer deposited on the non-recessed areas of the semiconductor wafer is removed.

However, if excessive or insufficient amounts of the metal layer are removed, then the transistor and/or interconnection element may malfunction. For example, if an excessive amount of metal is removed from the trenches that form the interconnections, then the interconnections may not be able to properly transmit electrical signals.

Additionally, the use of dielectric materials having low dielectric constants (low-k dielectrics) has been introduced as a way to reduce the signal delays at the interconnections of conductors. However, because low-c dielectric materials having porous microstructures, they also have low mechanical integrity and thermal conductivity as compared to other dielectric materials. Consequently, low-k dielectric materials typically cannot sustain the stress and pressure applied to them during a conventional damascene process.

In a conventional damascene process, a barrier layer may be formed over the metal or low-k dielectric materials. Because the barrier layer is typically formed by hard and chemically inert material, such as TaN, Ta, Ti, and TiN, the barrier layer is difficult to remove using CMP or electropolishing, except by using higher pad pressure during CMP or high voltage using electropolishing. In the case of CMP, higher pad pressure can increase surface defect density, or even delaminate the low-k dielectric. In the case of electropolishing, higher polishing voltage can remove excessive amounts of the metal, which can increase the line resistance. When conventional plasma etching is used to remove the barrier layer, over-etching is necessary in order to make sure that all of the barrier layer on non-recessed areas is removed. However, the over-etching can cause voids when the next cover layer is deposited. Metal atoms can diffuse out from the void and can even diffuse to the device gate region, which can make the semiconductor device malfunction.

### SUMMARY

In one exemplary embodiment, a metal layer formed on a semiconductor wafer is adaptively electropolished. A portion of the metal layer is electropolished, where portions of the metal layer are electropolished separately. Before electropolishing the portion, a thickness measurement of the portion of the metal layer to be electropolished is determined. The amount that the portion is to be electropolished is adjusted based on the thickness measurement.

In another exemplary embodiment, a metal layer formed on a semiconductor wafer is polished, where the metal layer is formed on a barrier layer, which is formed on a dielectric layer having a recessed area and a non-recessed area, and where the metal layer covers the recessed area and the non-recessed areas of the dielectric layer. The metal layer is polished to remove the metal layer covering the non-recessed area. The metal layer in the recessed area is polished to a height below the non-recessed area, where the height is equal to or greater than a thickness of the barrier layer.

### DESCRIPTION OF DRAWING FIGURES

The present invention can be best understood by reference to the following description taken in conjunction with the accompanying drawing figures, in which like parts may be referred to by like numerals:

FIG. 1 depicts an exemplary electropolishing module;

FIG. 2A depicts an exemplary thickness mapping of a metal layer formed on a semiconductor wafer;

FIGS. 2B and 2C depict a portion of the mapping depicted in FIG. 2A;

FIG. 3 depicts various mapping schemes;

FIG. 4 depicts an exemplary control system connected to a plurality of exemplary electropolishing modules;

FIG. 5 depicts an exemplary control system connected to a plurality of exemplary electropolishing modules through a plurality of subsystems;

FIGS. 6A to 6D depict an exemplary damascene process;

FIGS. 7A to 7D depict another exemplary damascene process;

FIGS. 8A to 8D depict still another exemplary damascene process; and

FIGS. 9A to 9D depict yet another exemplary damascene process.

### DETAILED DESCRIPTION

The following description sets forth numerous specific configurations, parameters, and the like. It should be recognized, however, that such description is not intended as a limitation on the scope of the present invention, but is instead provided as a description of exemplary embodiments.

I. Adaptive Electropolishing

As described earlier, in forming transistor and interconnection elements on a semiconductor wafer, metal is deposited and removed from the semiconductor wafer. More specifically, a layer of metal (i.e., a metal layer) is formed on the semiconductor wafer using a deposition process, such as chemical vapor deposition (CVD), physical vapor deposition (PVD), atomic layer deposition (ALD), electroplating, electroless plating, and the like. The metal layer is then removed using an etching or polishing process, such as chemical mechanical polishing (CMP), electropolishing, and the like.

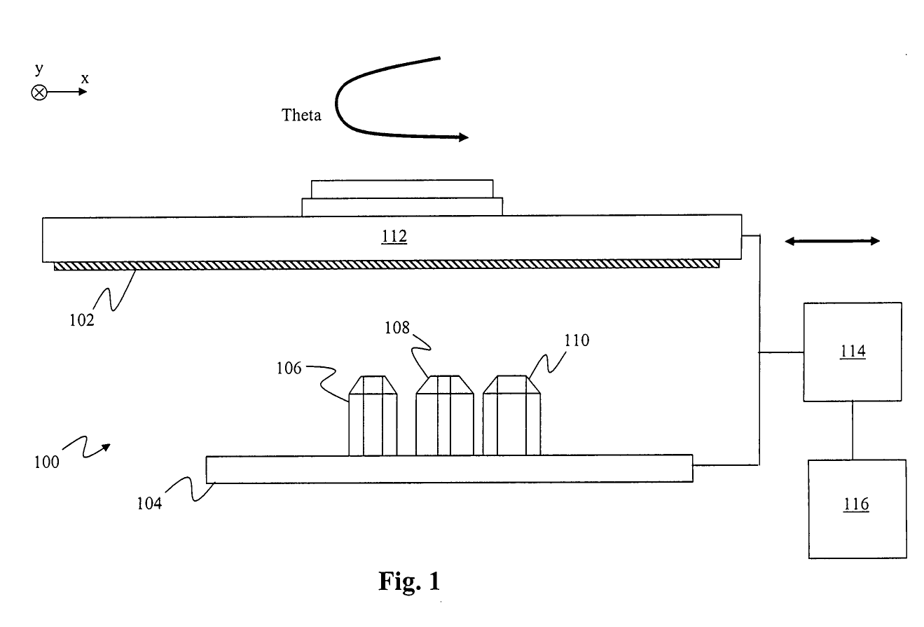

With reference to FIG. 1, in one exemplary embodiment, an electropolishing module 100 can be used to remove/polish a metal layer formed on semiconductor wafer 102. In the present exemplary embodiment, wafer 102 is held by wafer chuck 112, which rotates wafer 102 about angle theta and translates wafer 102 laterally, such as in the x-direction as depicted in FIG. 1. While wafer 102 is rotated and translated by wafer chuck 112, an electrolyte is applied to the metal layer formed on wafer 102 through nozzle 108 and/or nozzle 110. As depicted in FIG. 1, nozzle 108 can be configured to apply a narrower stream of electrolyte than nozzle 110. As such, nozzle 108 can be used for a more precise polishing than nozzle 110. For example, nozzle 110 can be used for an initial rough polishing, where an initial amount of the metal layer is polished from the surface of wafer 102, then nozzle 108 can be used for a subsequent finer polishing, where the metal layer is polished more uniformly than during the initial rough polishing. In the present exemplary embodiment, an end-point detector 106 can be used to measure the thickness of the metal layer on the surface of wafer 102. In FIG. 1, end point detector 106, nozzle 108, and nozzle 110 are depicted as being disposed adjacent to each other on a nozzle plate 104. It should be recognized, however, that end point detector 106, nozzle 108, and nozzle 110 can be arranged in various configurations and mounted in a variety of manners. Additionally, it should be recognized that any number of nozzles, including one nozzle, can be used to electropolish the metal layer on wafer 102. Furthermore, it should be recognized that end point detector 106, nozzle 108 and/or nozzle 110 can translate either instead of or in addition to translating wafer 102 using wafer chuck 112.

For a more detailed description of an exemplary electropolishing process and system, see U.S. Pat. No. 6,394,152 B1, entitled METHODS AND APPARATUS FOR ELECTROPOLISHING METAL INTERCONNECTIONS ON SEMICONDUCTOR DEVICES, filed on Jul. 2, 1999; U.S. Pat. No. 6,248,222 B 1, entitled METHODS AND APPARATUS FOR HOLDING AND POSITIONING SEMICONDUCTOR WORKPIECES DURING ELECTROPOLISHING AND/OR ELECTROPLATING OF THE WORKPIECES; and U.S. Provisional Application Ser. No. 60/372,566, entitled METHOD AND APPARATUS FOR ELECTROPOLISHING AND/OR ELECTROPLATING, filed on Apr. 14, 2002, the entire contents of which are incorporated herein by reference. For a more detailed description of an exemplary end point detector, see U.S. Pat. No. 6,447,668, entitled METHOD AND APPARATUS FOR END-POINT DETECTION, filed on May 12, 2000, the entire content of which is incorporated herein by reference.

In the present embodiment, wafers are generally processed using a recipe that includes various processing parameters, such as liquid flow rate, current or voltage set-point, center-to-edge distance, initial rotational speed, polishing duration, center polishing rotational speed, nozzle type, current or voltage table, bulk ratio table for constant current, repetition setting, and the like. Because wafers processed using the same deposition process will generally have similar metal layer thickness profiles, the wafers can be initially polished using similar polishing recipes.

However, as described above, in polishing the metal layer formed on a wafer, polishing too much or too little of the metal layer can result in the semiconductor device malfunctioning. Thus, in the present exemplary embodiment, the thickness of the metal layer on a wafer is used to adaptively electropolish the metal layer. More particularly, before electropolishing a portion of the metal layer formed on the wafer, the thickness of the portion to be electropolished is determined, and the amount that the portion is electropolished is adjusted based on the determined thickness.

For example, a control system 114 can be connected to wafer chuck 112 and nozzle 108 and nozzle 110. Based on the position of wafer chuck 112, control system 114 can determine the location of the portion of the metal layer on wafer 102 to be electropolished. Control system 114 determines the thickness of the portion of the metal layer to be electropolished, and adjusts the amount that the portion is electropolished by nozzle 108 and/or nozzle 110.

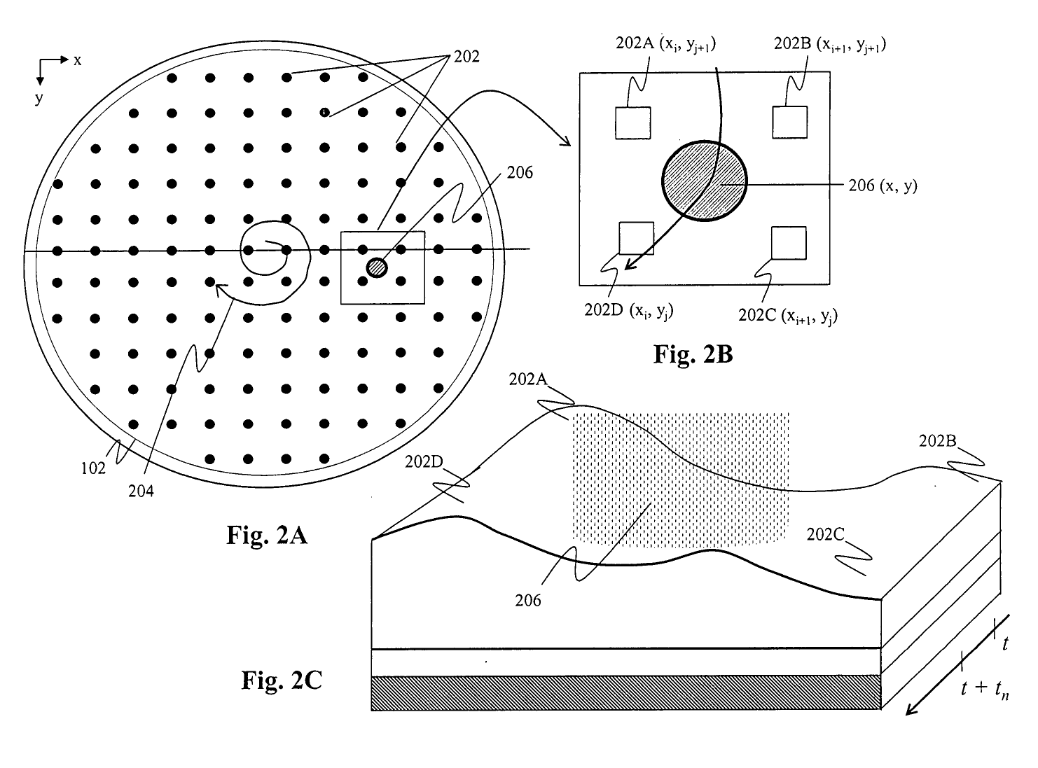

In one exemplary embodiment, before wafer 102 is processed in polishing module 100, a substrate thickness metrology tool 116 is used to measure and map the thickness of the metal layer on wafer 102. With reference to FIG. 2A, metrology tool 116 (FIG. 1) can provide thickness measurements at various locations 202 on wafer 102. Note that locations 202 can be mapped using various coordinate systems. For example, as depicted in FIG. 2A, a simple x and y coordinate axes can be used. Alternatively, radius and the angle theta, corresponding to the angle of rotation of wafer 102, can be used. Control system 114 (FIG. 1) can then use the mapping of the thickness of the metal layer on wafer 102 to obtain the thickness of a portion of the metal layer prior to electropolishing the portion.

As depicted in FIG. 2A, the mapping of the thickness of the metal layer on wafer 102 may include gaps, meaning locations where the thickness of the metal layer is not known. More particularly, as depicted in FIG. 2A, the rotation and translation of wafer 102 results in the stream of electrolyte applied by nozzle 108 (FIG. 1) and/or nozzle 110 (FIG. 1) in a spiral path 204. As also depicted in FIG. 2A, the stream of electrolyte may be applied in a location 206, where the thickness of the metal layer is not known. Thus, in the present exemplary embodiment, thickness measurements from two or more locations 202, where the thickness of the metal layer is known are used to determine the thickness of the metal layer in location 206.

For example, as depicted in FIG. 2B, the thickness of the metal layer at location 206 is determined based on the thickness of the metal layer at locations 202A, 202B, 202C, and 202D. Note that in accordance with the x and y coordinate system used in FIG. 2A, location 206 corresponds to position (x, y), and locations 202A, 202B, 202C, and 202D correspond to positions (xᵢ, yⱼ₊₁), (xᵢ₊₁, yⱼ₊₁), (xᵢ₊₁, yⱼ), and (xᵢ, yⱼ), respectively. FIG. 2C depicts the variation in the thickness of the metal layer in a perspective view.

In the present example, assume that the thickness of the metal layer at location 206 is characterized by the following expression:
T=Ax+By+Cxy+D (1)
Additionally, the thickness Tᵢⱼ at (xᵢ,yⱼ), thickness Tᵢⱼ₊₁ at (xᵢ,yⱼ₊₁), and T_{i+1,j} at (xᵢ₊₁, yj), and thickness T_{i+1,j+1} at (xᵢ₊₁,yⱼ₊₁) are assumed to be characterized by the following expressions:
T_{i,j}=Axᵢ+Byⱼ+Cxᵢyᵢ+D (2)
T_{i,j+1}=Axᵢ+Byⱼ₊₁+Cxᵢyⱼ₊₁+D (3)
T_{i+1,j}=Axᵢ₊₁+Byⱼ+Cxᵢ₊₁yⱼ+D (4)
T_{i+1,j+1}=Axᵢ₊₁+Byⱼ₊₁+C (5)
The values of A, B, C, and D can then be obtained by solving equations (2)-(5) in the following manner:
C=(T_{i,j}−T_{i,j+1}−T_{i+1,j}+T_{i+1,j+1})/[(xᵢ−xᵢ₊₁)*(yⱼ−yⱼ₊₁)]
B=(T_{i,j}−T_{i,j+1})/(yⱼ−yⱼ₊₁)−xᵢ*D
A=(T_{i,j}−T_{i+1,j})/(xᵢ−xᵢ₊₁)−yⱼ*D
D=T_{i,j}−xᵢ*B−yᵢ*[(T_{i,j}−T_{i,j+1})/(yⱼ−yⱼ₊₁)]

It should be recognized that any number of locations 202, where the thickness of the metal layer is known, can be used to determine the thickness of the metal layer at location 206. For example, for a more accurate interpolation than that described above, the thickness of the metal layer at location 206 can be assumed to be characterized by the following expression:
T=Ax²+By²+Cxy+Dx+Ey+F (6)
The Thickness T at (x, y) can be interpolated using 6 locations closest to location 206, and the constants A, B, C, D, E, and F can be obtained by solving 6 equations in the same manner as the constants A, B, C, and D were solved above when using 4 locations.

With reference again to FIG. 1, in the present exemplary embodiment, thickness measurements of the metal layer on wafer 102 can be obtained using end point detector 106. More particularly, wafer 102 can be rotated and translated adjacent end point detector 106 in the same manner as when wafer 102 is electropolished using nozzle 108 and/or nozzle 110. Thus, thickness measurements of the metal layer on wafer 102 can be obtained along the same path 204 (FIG. 2) as would be followed when the metal layer is electropolished-using nozzles 108 and/or nozzle 110.

For example, when end point detector 106 is an optical sensor, reflectivity of the surface of wafer 102 adjacent to end point detector 106 can be recorded as wafer 102 is rotated and translated. The thickness of the metal layer at a location, such as location 206 (FIG. 2) can then be calculated using the following formula:
T(x, y)=P(T)*R(x, y) (7)
where R(x, y) is the reflectivity of metal film at location 206 (FIG. 2) measured by end point detector 106, and P(T) is the conversion factor of reflectivity to thickness, which itself is a function of thickness. P(T) can be determined by using a set of metal layers with different thickness that are known, then correlating the known thicknesses to the reflectivity of the metal layers. The determined conversion factor, P(T), can then be used to determine the thickness that corresponds to a reflectivity of a metal layer with unknown thickness.

Alternatively, the known thicknesses and the corresponding reflectivities can be stored, such as in a look-up table, in a computer, such as in control system 114. For example, the look-up table can include a thickness matrix stored in computer memory as follows:
T_{1,1} T_{1,2} T_{1,3} . . . T_{1,m}
T_{2,1} T_{2,2} T_{2,3} . . . T_{2,m}
T_{3,1} T_{3,2} T_{3,3} . . . T_{3,m}
T_{n,1} T_{n,2} T_{n,3} . . . T_{n,m}
with each thickness in the thickness matrix having a corresponding reflectivity.

After measuring the reflectivity at location 206 (FIG. 2) using end point detector 106, control system 114 can determine the thickness T(x, y), such as by using a conversion factor, P(T) or a look-up table. The metal layer can then be electropolished using the thickness measurement. The process can be repeated until the reflectivity recorded by end-point detector 106 is within a pre-set range. It should be noted that the pre-set range of reflectivity can depend on various factors, such as metal pattern density, over-polishing range, and the like. In general, the less the patterned density, the lower pre-set of reflectivity. Also, the preset reflectivity can vary based on pattern density. The preset reflectivity can be calculated based on pattern density of mask or measured by one polished wafer with minimum metal recess. For a more detailed described of calculating the preset reflectivity, see U.S. Pat. No. 6,447,668, entitled METHOD AND APPARATUS FOR END-POINT DETECTION, filed on May 12, 2000, the entire content of which is incorporated herein by reference.

It should be recognized that end-point detector 106 can be various types of sensors. For example, end-point detector 106 can be an eddy-current sensor. Thus, end-point detector 106 is used to measure eddy currents rather than reflectivity, and the thickness of the metal layer is determined based on the measured eddy currents rather than the measured reflectivity.

While thickness measurements obtained using end point detector 106 can follow the same path as the path followed when the metal layer is electropolished, gaps may still exist in the thickness measurements. For example, the thickness measurements can be taken at intervals rather than continuously in order to increase throughput When gaps exist in the thickness measurements, the interpolation process described above can be used to obtain thickness measurements in locations where thickness measurements are not known.

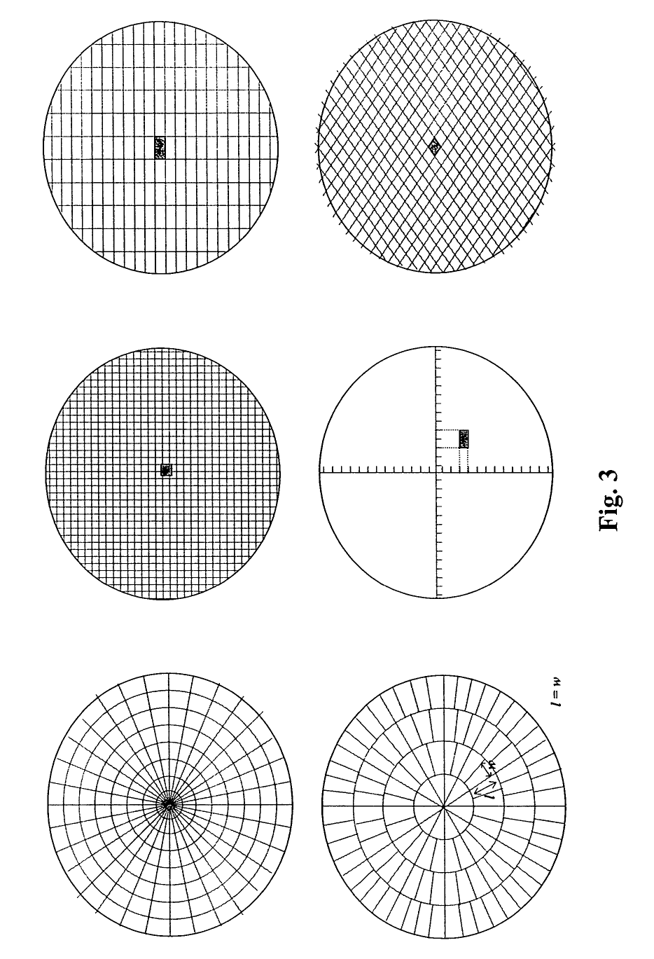

Additionally, in the present exemplary embodiment, a grid-by-grid imaging can be used to map and locate any position on a wafer. More particularly, the surface of a wafer can be mapped into pixel partitions, where each pixel partition corresponds to a field that can be measured using end point detector 106 (FIG. 1). FIG. 3 depicts various exemplary pixel partitions. End point detector 106 (FIG. 1) can measure the reflectivity for a given position (x, y), or a pixel, preferably with a size of 2.5 mm by 2.5 mm, starting from center of a wafer to the edge of a wafer or from the edge to the center. End-point detector 106 (FIG. 1) can move from one pixel at a time and record the reflectivity data for each pixel until all the pixels are recorded, such as up to 11,494 pixels (i.e., πR²/(2.5)²) for a 200 mm wafer.

In the present exemplary embodiment, an initial rough electropolishing is performed using an initial thickness measurement obtained from a substrate thickness metrology tool prior to electropolishing the wafer. After the initial rough electropolishing is completed, an intermediate thickness measurement of the metal layer is obtained, for example, using an end point detector. The metal layer is then electropolished again using the intermediate thickness measurement The initial rough electropolishing can be completed when the thickness of the metal layer is below a threshold thickness, such as about 1000 Å. It should be recognized, however, that the metal layer can be electropolished based on the initial thickness measurement and without the intermediate thickness measurement. Alternatively, the metal layer can be electropolished based on the thickness measurement obtained, for example, using an end-point detector without the initial thickness measurement.

As described above, in the present exemplary embodiment, the amount that a portion of the metal layer is electropolished is adjusted based on the thickness measurement of the portion. The amount that the portion is electropolished can be adjusted by varying the current and/or voltage applied to the stream of electrolyte applied to the portion. For example, the applied polishing current can be determined based on the thickness as follows:
I=kT(x, y) (7)
where k is the factor related to polishing rate. In addition to varying the current and/or voltage applied to the stream of electrolyte, it should be recognized that the amount of time the stream of electrolyte is applied to the portion (i.e., polishing duration) can be adjusted based on the thickness measurement of the portion. Moreover, any combination of current, voltage, and polishing duration can be adjusted based on the thickness measurement of the portion.

Thus, with reference to FIG. 1, in the present exemplary embodiment, control system 114 determines the thickness measurement of a portion of the metal layer to be electropolished, then adjusts the amount that the portion is electropolished based on the determined thickness measurement. As described above, control system 114 can adjust the current and/or voltage applied to the stream of electrolyte applied by nozzle 108 and/or nozzle 110. Control system 114 can also adjust the polishing duration by controlling the rate of rotation and/or translation of wafer chuck 112.

In the present exemplary embodiment, the amount of delay from the time when control system 114 determines the adjustment to make and when the adjustment is implemented (i.e., Δt) is used as an offset time in advance of when control system 114 determines the adjustments, to be made for a portion of the metal layer control system 114 before that portion is electropolished. For example, when the current applied to the stream of electrolyte applied by nozzle 108 is to be adjusted for a portion of the metal layer, control system 114 determines the current to be applied in advance by at least the offset time (i.e., Δt) of nozzle 108 reaching the portion to be electropolished.

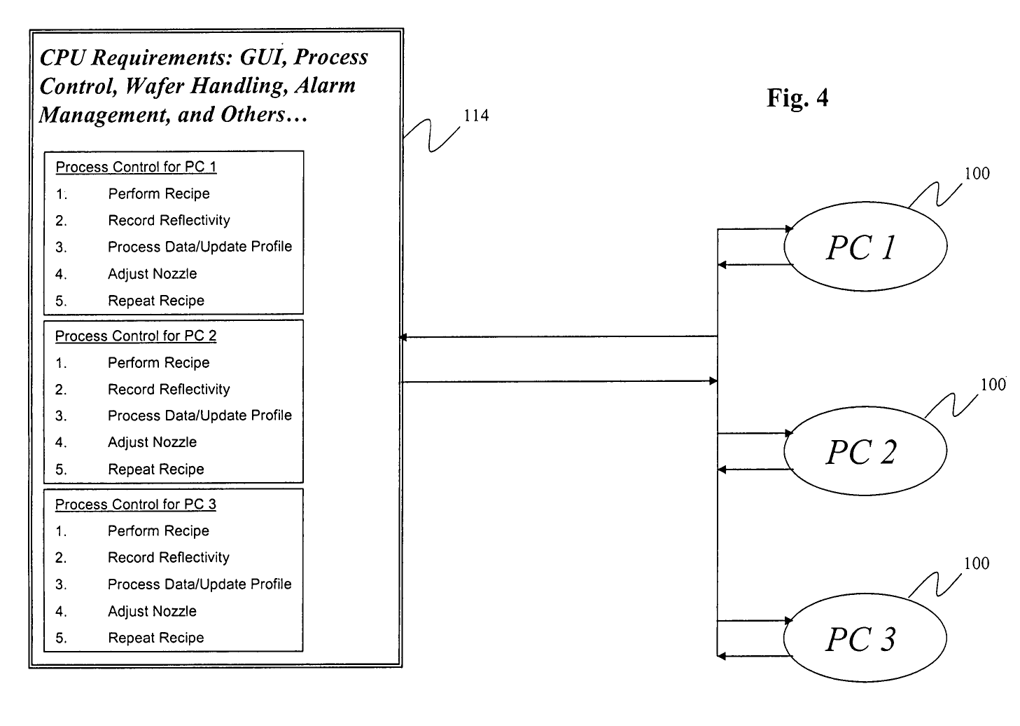

With reference now to FIG. 4, control system 114 can be connected to a plurality of electropolishing modules 100 (e.g., processing chamber 1 (PC1), PC2, and PC3). As depicted in FIG. 4, control system 114 executes the process control for each electropolishing module 100. For example, for each electropolishing module 100, control system 114 executes the polishing recipe, records thickness measurements (e.g., reflectivity data), processes the thickness measurements and updates the metal film thickness profile, adjusts the electropolishing (e.g., adjusting the current or voltage applied to the stream of electrolyte applied by a nozzle), and repeats the polishing recipe for each wafer to be electropolished. Control system 114 also performs various additional tasks, such as graphical user interface, wafer handling, alarm management, and the like.

However, the processing and computing load required of control system 114 can reduce response time for tasks, such as read-outs, electrical output, and mechanical motion. Increasing the number of loads that control system 114 is required to handle can reduce the completion time for each load. Thus, in the present exemplary embodiment, control system 114 includes a plurality of distributed subsystems, where task-oriented functions are off loaded to individual subsystems, such as a motion server block controller.

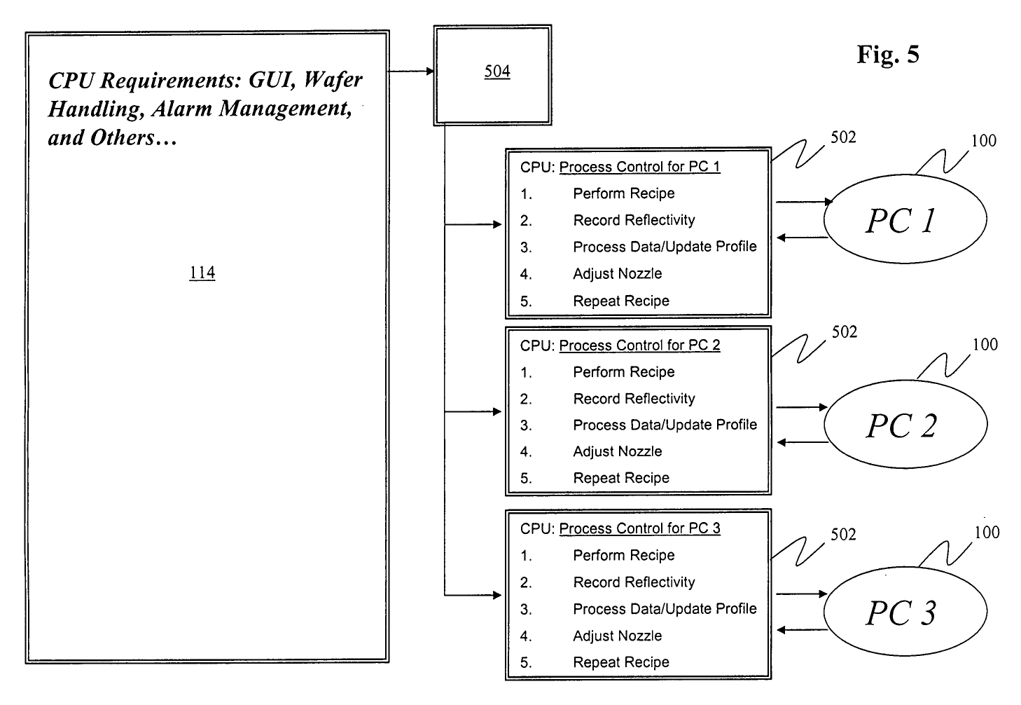

More particularly, with reference now to FIG. 5, one subsystem 502 is dedicated to one electropolishing module 100 (e.g., PC1, PC2, or PC3). The distributive subsystem depicted in FIG. 5 reduces the time lag that can be associated with a central system depicted in FIG. 4. In the exemplary embodiment depicted in FIG. 5, a PC based control system 114 receives and sends data to each subsystems 502 using a device-to-device transmission media 504, such as RS485, DeviceNet, and the like.

For example, each subsystem 502 can perform the same set of tasks for each electropolishing module 100. As depicted in FIG. 5, one subsystem 502 can be dedicated to operate the chuck, motor drives, nozzles, and end-point detector, and to process the data for digital IO and analog IO for PC1. Simultaneously, the other subsystems 502 can be dedicated to their respective electropolishing modules 100. For example, another subsystem 502 can be dedicated to operate the chuck, motor drives, nozzles, and end-point detector, and to process the data for digital IO and analog IO for PC2.

Under the distributive arrangement, each subsystem 500 can exert better and finer control in both mechanical and electrical performance (i.e., to record both rotational angle and location of the wafer with remaining metal layer and to control nozzle functions based on the reflectivity recorded for the given location in 4 milliseconds or better). With each subsystem 502 having increased processing capacity, the present exemplary embodiment can add or extrapolate other values or tables in the recipe based on the reflectivity data to achieve finer control of the polishing.

Moreover, as the result of distributing processing requirement of the wafer electropolishing distributed to subsystems 502, control system 114 and subsystems 502 can have more available processing power to operate or perform other tasks. In particular, additional tools and/or applications can be added to the polishing process without diminishing the speed or practicality of such tool configurations. For example, an inline metrology tool can be added to measure the profile of each wafer before the wafer is loaded to an electropolishing module. The inline metrology tool can measure the thickness of the metal layer on a wafer for a subsystem 502 or control system 114 to determine the required current output to achieve a more flat uniform metal surface. Subsystem 502 or control system 114 can then generate a new table with data, such as the distance versus current rate times user defined set-points.

II. Removing Barrier and Sacrificial Layers

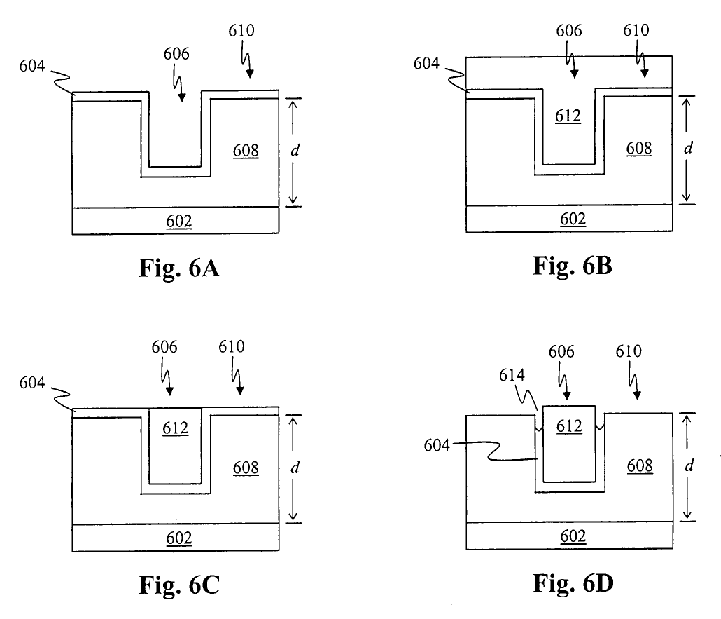

FIGS. 6A-6D depict an exemplary damascene process that can be used to form interconnections in a semiconductor device. In particular, with reference to FIG. 6A, the semiconductor device can include a dielectric material 608 having recessed area 606 and non-recessed area 610, where recessed area 606 can be a structure such as a wide trench, a large rectangular structure, and the like. A barrier layer 604 can be deposited on dielectric material 608 by any convenient deposition method, such as CVD, PVD, ALD, and the like, such that barrier layer 604 covers both recessed area 606 and non-recessed area 610. For a more detailed description of dielectric material and barrier layer, see U.S. patent application Ser. No. 10/380,848, entitled METHOD FOR INTEGRATING COPPER WITH ULTRA-LOW K DIELECTRICS, filed on Mar. 14, 2003; U.S. patent application Ser. No. 10/108,614, entitled ELECTROPOLISHING METAL LAYERS ON WAFERS HAVING TRENCHES OR VIAS WITH DUMMY STRUCTURES, filed on Mar. 27, 2002, which claims priority of an earlier filed provisional application U.S. Ser. No. 60/286,273, of the same title, filed on Apr. 24, 2001. The entire content of these applications are incorporated herein by reference.

In the present exemplary process, with reference to FIG. 6B, a metal layer 612 can be deposited on barrier layer 604 by any convenient method, such as PVD, CVD, ALD, electroplating electroless plating, and the like. Next, with reference to FIG. 6C, metal layer 612 is polished back using CMP, electropolishing, and the like, such that metal layer 612 is removed from non-recessed area 610, while metal layer 612 is left in recessed area 606. Metal layer 612 can include various electrically conductive materials, such as copper, aluminum, nickel, chromium, zinc, cadmium, silver, gold, rhodium, palladium, platinum, tin, lead, iron, indium, super-conductor materials, and the like. Metal layer 612 can also include an alloy of any of the various electrically conductive materials, or compound of superconductor. Preferably, metal layer 612 includes copper and its alloys.

Now, with reference to FIG. 6D, after removing metal layer 612 from non-recessed area 610, barrier layer 604 can be removed from non-recessed area 610 by any convenient method such as wet etching, dry chemical etching, dry plasma etching, and the like. In order to entirely remove barrier layer 604 on non-recessed area 610, over-etching is required. However, as depicted in FIG. 6D, over-etching can produce a notch 614. When the next cover layer, such as SiN and the like, are deposited in the present exemplary process, notch 614 can become a void, which can lead to metal bleeding. The bled metal can diffuse through dielectric material 608 and down to the device gate region, causing the semiconductor device to malfunction.

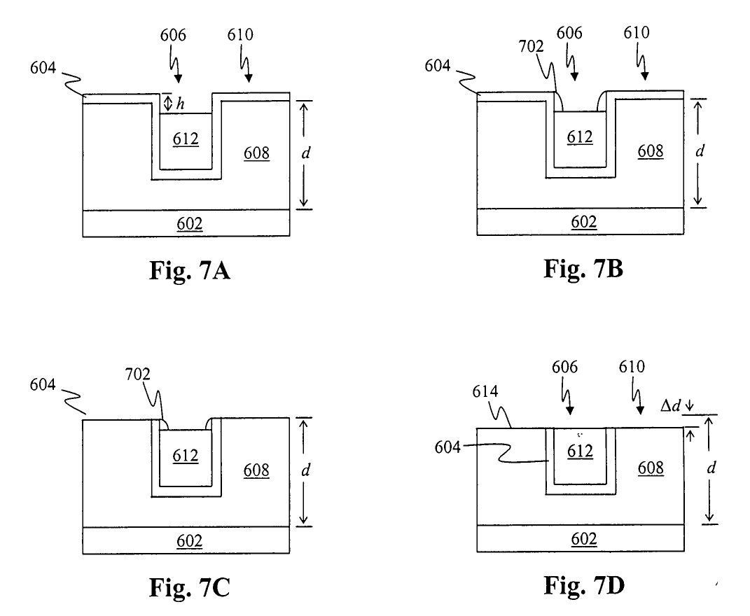

As shown in FIGS. 7A-7D, a combination of overpolish using electropolish and plasma etching can be used to address this problem. In the present exemplary process, with reference to FIG. 7A, metal layer 612 in recessed area 606 is overpolished using electropolishing, wet etching, and the like, so that there exists h micron in height between the top of barrier layer 604 and the surface of metal layer 612 within recessed area 606, where the height h is equal to or greater than the thickness of barrier layer 604. It should be recognized that electropolishing can have better control and therefore cause less process problems when trying to overpolish metal layer 612 in recessed area 606 as compared with wet etching method. For a description of electropolishing, see U.S. Pat. No. 6,395,152, entitled METHODS AND APPARATUS FOR ELECTROPOLISHING METAL INTERCONNECTIONS ON SEMICONDUCTOR DEVICES, filed on Jul. 2, 1999, which is incorporated in its entirety herein by reference.

Next, with reference to FIG. 7B, additives, such as CF₄/O₂, SF₆/O₂, and the like, are added to the etching gases, Ta, C, and F, to form a residue 702 on barrier layer 604 and metal layer 612 within recessed area 606. As shown in FIG. 7C, when barrier layer 604 is being etched away, the presence of residue 702 can prevent barrier layer 604 between dielectric material 608 and metal layer 612 in recessed area 606 from being over-etched.

The following table, Table 1, provides an exemplary range of parameters that can be employed in a plasma dry etch process to remove barrier layer 604:

TABLE 1

| | |
|---|---|
| Plasma Power: | 500 to 2000 W |
| Vacuum: | 30 to 100 mTorr |
| Temperature of wafer: | approximately 20° C. |
| Gas and flow rate: | SF₆ = 50 sccm, CF₄ = 50 sccm, or |
| | O₂ = 10 sccm |
| Gas pressure: | 0.1 to 50 mTorr |
| Removal rate of TaN: | 250 nm/min |
| Removal rate of TiN: | 300 nm/min |
| Removal rate of SiO₂: | 200˜400 nm/min |

These parameters result in a removal rate of TaN and TiN, two possible barrier layer 604 materials, close to that of SiO₂, a possible dielectric material 608 material. The selectivity can be selected in this manner to reduce etching or damaging the underlying dielectric material 608 during the removal of barrier layer 604. It should be noted, however, that other selectivity can be obtained by varying the parameters.

Now with reference to FIG. 7D, a portion of recessed area 606 and non-recessed area 610 of about Δd can be removed by using plasma etching process, or dry chemical cleaning, or any other convenient process. The etch rate of barrier layer 604 should be set equal or lower than that of dielectric material 608 in order to make sure that barrier layer 604 is equal or higher than dielectric material 608 in height. Therefore, no voids will be formed when the next top layer is deposited.

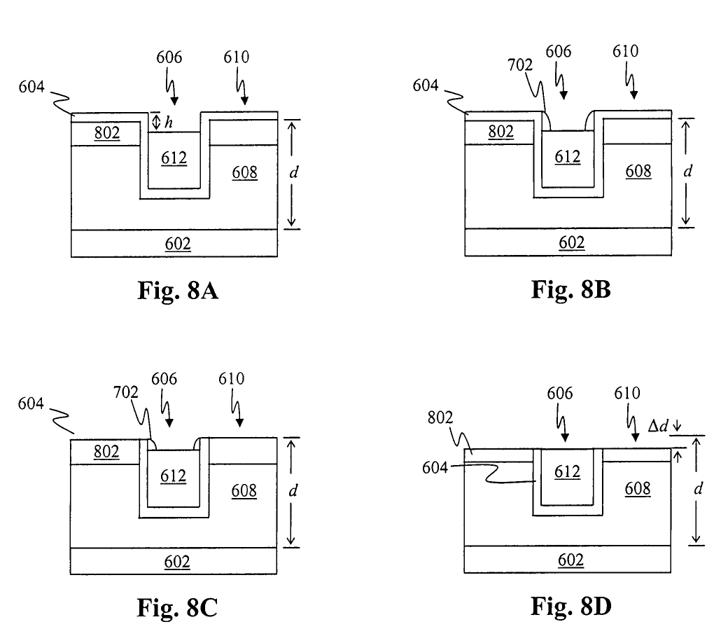

In FIGS. 8A to 8D, another exemplary process is shown. The exemplary process shown in FIGS. 8A to 8D is similar in many respects to the process shown in FIGS. 7A to 7D, except that a hard mask layer 802 is deposited on dielectric material 608 before the wafer undergoes etching and deposition processes that form recessed areas such as 606. As shown, hard mask layer 802 can prevent etching of dielectric material 608 underneath of bard mask layer 802 during barrier removal processes and therefore avoid the performance degradation of dielectrics, especially low-k dielectrics. Recess h should be less than the sum of thickness of barrier layer 604 and the thickness of hard mask 802.

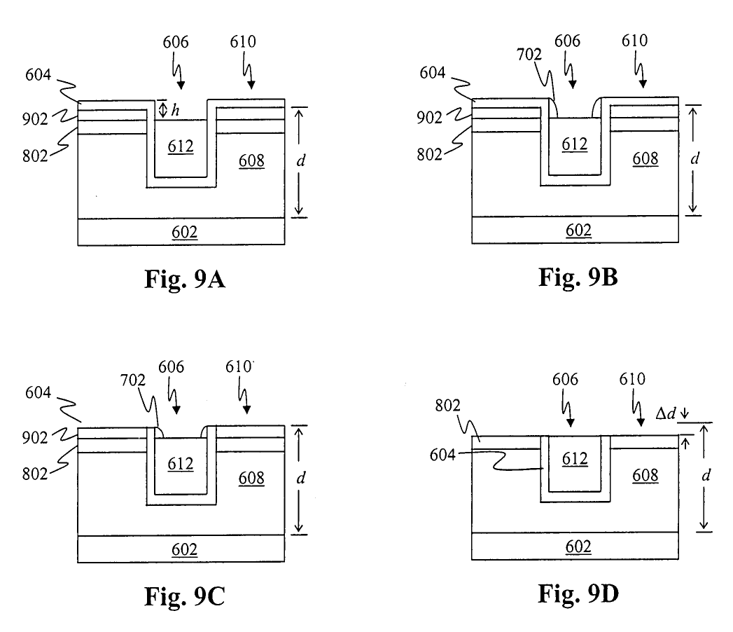

In FIGS. 9A to 9B, another exemplary process is shown. Similar to FIGS. 8A to 8D, the exemplary process shown in FIGS. 9A to 9D is similar in many respects to the process shown in FIGS. 7A to 7D, except that in addition to hard mask layer 802, a sacrificial layer 902 is deposited on top of hard mask layer 802. While hard mask layer 802 has lower removal rate than that of barrier layer 604, in this exemplary process, sacrificial layer 902 with a removal rate equal or greater than that of barrier layer 604 is used.

In both FIGS. 8A to 8D and FIGS. 9A to 9D, hard mask layer 802 can be selected from SiN, SiC, SiO₂, SiON, diamond film, and the like. Sacrificial layer 902 can be selected from SiN, SiO₂, SiON, and the like.

Although exemplary embodiments have been described, various modifications can be made without departing from the spirit and/or scope of the present invention. Therefore, the present invention should not be construed as being limited to the specific forms shown in the drawings and described above.

1. A method of adaptively electropolishing a metal layer formed on a semiconductor wafer, the method comprising:
electropolishing a portion of the metal layer, wherein portions of the metal layer are electropolished separately;
before electropolishing the portion, determining a thickness measurement of the portion of the metal layer to be electropolished; and
adjusting an amount that the portion is to be electropolished based on the thickness measurement.

2. The method of claim 1, wherein electropolishing a portion of the metal layer comprises:
applying a stream of electrolyte to the portion of the metal layer through a nozzle adjacent to the portion of the metal layer.

3. The method of claim 2, wherein the wafer is held, rotated, and translated using a wafer chuck while the nozzle is held stationary adjacent to the metal layer.

4. The method of claim 2, wherein the wafer is held and rotated using a wafer chuck while the nozzle is translated adjacent to the metal layer.

5. The method of claim 2, wherein adjusting an amount that the portion is to be electropolished comprises:
adjusting a polishing current or voltage applied to the stream of electrolyte.

6. The method of claim 2, wherein adjusting an amount that the portion is to be electropolished comprises:
adjusting a polishing duration of the portion.

7. The method of claim 1, wherein determining a thickness measurement comprises:
obtaining a map of the thickness measurement of the metal layer determined using a thickness metrology tool.

8. The method of claim 7, wherein determining a thickness measurement further comprises:
measuring thickness measurements of the metal layer using an end-point detector; and
wherein adjusting an amount that the portion is to be electropolished comprises:
adjusting the amount that the portion is to be electropolished during an initial polishing using the map of the thickness measurement of the metal layer determined using the thickness metrology tool; and
adjusting the amount that the portion is to be electropolished during a subsequent polishing using the thickness measurement measured using the end point detector.

9. The method of claim 7, further comprising:
interpolating a thickness measurement of a portion of the metal layer not having a thickness measurement on the map based on a plurality of thickness measurements of portions of the metal layer having thickness measurements on the map.

10. The method of claim 1, wherein determining a thickness measurement comprises:
measuring thickness measurements of the metal layer using an end point detector adjacent to the metal layer.

11. The method of claim 10, wherein the wafer is held, rotated, and translated using a wafer chuck while the end point detector is held stationary adjacent to the metal layer.

12. The method of claim 10, wherein the thickness measurements are mapped using a plurality of pixel partitions, wherein a pixel position corresponds to a field that can be measured using the end point detector.

13. The method of claim 10, further comprising:
determining an end to polishing the portion based on a metal density of pattern on the wafer.

14. The method of claim 10, wherein the end point detector is an optical sensor.

15. The method of claim 10, wherein the end point detector is an eddy current sensor.

16. A system for adaptively electropolishing a metal layer formed on a semiconductor wafer, the method comprising:
an electropolishing module configured to electropolish portions of the metal layer separately; and
a control system configured to:
determine a thickness measurement of a portion of the metal layer before the portion is electropolished, and
adjust an amount that the portion is electropolished based on the thickness measurement.

17. The system of claim 16, wherein the electropolishing module comprises:
a nozzle configured to apply a stream of electrolyte to the portion of the metal layer.

18. The system of claim 17, further comprising:
a wafer chuck configured to hold, rotate, and translate the wafer while the nozzle is held stationary adjacent to the nozzle.

19. The system of claim 17, wherein the nozzle is configured to translate, and further comprising:
a wafer chuck configured to hold and rotate the wafer.

20. The system of claim 17, wherein the control system is configured to adjust a polishing current or voltage applied to the stream of electrolyte or adjust a polishing duration of the portion.

21. The system of claim 16, wherein the control system is configured to determine the adjustment to the amount that the portion is electropolished in advance of electropolishing the portion by an offset time.

22. The system of claim 16, further comprising:
a thickness metrology tool, wherein the control system obtains a map of the thickness measurement of the metal layer from the thickness metrology tool.

23. The system of claim 16, wherein the electropolishing module comprises:
an end point detector configured to measure the thickness of the metal layer.

24. The system of claim 23, wherein the electropolishing module further comprises:
a wafer chuck configured to hold, rotate, and translate the wafer while the end point detector is held stationary adjacent to the metal layer.

25. The system of claim 23, wherein the electropolishing module further comprises:
a wafer chuck configured to hold and rotate the wafer while the end point detector is translated.

26. The system of claim 23, wherein the end point detector is an optical sensor or an eddy current sensor.

27. The system of claim 23, wherein the end-point detector is configured to determine an end to polishing the portion based on a metal density of pattern on the wafer.

28. The system of claim 16, wherein the electropolishing module comprises:
a first processing chamber;
a first subsystem configured to control the first process chamber;
a second processing chamber; and
a second subsystem configured to control the second process chamber,
wherein the control system is connected to the first and second subsystems.

29. A method of polishing a metal layer formed on a semiconductor wafer, wherein the metal layer is formed on a barrier layer, which is formed on a dielectric layer having a recessed area and a non-recessed area, and wherein the metal layer covers the recessed area and the non-recessed areas of the dielectric layer, the method comprising:
polishing the metal layer to remove the metal layer covering the non-recessed area; and
polishing the metal layer in the recessed area to a height below the non-recessed area, wherein the height is equal to or greater than a thickness of the barrier layer.

30. The method of claim 29, wherein polishing the metal layer comprises electropolishing the metal layer.

31. The method of claim 30, wherein electropolishing the metal layer comprises:
applying a stream of electrolyte to a portion of the metal layer through a nozzle adjacent to the portion of the metal layer.

32. The method of claim 31, further comprising:
holding, rotating, and translating the wafer using a wafer chuck while the nozzle is held stationary.

33. The method of claim 31, further comprising:
holding and rotating the wafer using a wafer chuck while the nozzle is translated.

34. The method of claim 29, further comprising:
after polishing the metal layer, removing the barrier layer from the non-recessed area using plasma etching.

35. The method of claim 34, wherein plasma etching comprises using an etching gas, and wherein an additive is added to the etching gas to form a residue on the metal layer and the barrier layer in the recessed area.

36. The method of claim 34, further comprising:
removing a portion of the recessed and non-recessed area using plasma etching, wherein the etch rate of the barrier layer within the recessed area is equal to or higher than the etch rate of the dielectric layer.

37. The method of claim 29, wherein a hard mask layer is disposed between the dielectric layer and barrier layer, and wherein the height is less than the sum of the thickness of the barrier layer and a thickness of the hard mask layer.

38. The method of claim 37, wherein a sacrificial layer is disposed between the hard mask layer and barrier layer, wherein the hard mask layer has a lower removal rate than the barrier layer and the sacrificial layer has a removal rate equal to or greater than the barrier layer.

39. The method of claim 29, wherein the dielectric layer includes a low-k dielectric material, and the metal layer includes copper.

40. A layer of a semiconductor wafer comprising:
a dielectric layer having recessed and non-recessed area;
a barrier layer deposited above the dielectric layer; and
a metal layer deposited on the barrier layer, wherein the metal layer is removed from the non-recessed area of the dielectric layer and polished in the recessed area to a height below the non-recessed area, wherein the height is equal to or greater than a thickness of the barrier layer.

41. The layer of a semiconductor wafer of claim 40, further comprising:
a hard mask layer disposed between the dielectric layer and barrier layer, wherein the height is less than the sum of the thickness of the barrier layer and a thickness of the hard mask layer.

42. The layer of a semiconductor wafer of claim 41, further comprising:
a sacrificial layer disposed between the hard mask layer and barrier layer, wherein the hard mask layer has a lower removal rate than the barrier layer and the sacrificial layer has a removal rate equal to or greater than the barrier layer.

43. The layer of semiconductor wafer of claim 40, wherein the dielectric layer includes a low-k dielectric material, and the metal layer includes copper.
